(19) United States
(12) Patent Application Publication
(10) Pub. No.: US 2014/0175474 A1
(43) Pub. Date: Jun. 26, 2014

(54) SEMICONDUCTOR LIGHT EMITTING DEVICE AND METHOD OF MANUFACTURING THE SAME

(71) Applicant: Samsung Electronics Co., Ltd., Suwon-si (KR)

(72) Inventors: Sang Heon HAN, Suwon-si (KR); Jong Pa HONG, Yongin-si (KR); Seung Hyun KIM, Seoul (KR); Yun Hee SHIN, Suwon-si (KR); Jeong Wook LEE, Yongin-si (KR)

(73) Assignee: SAMSUNG ELECTRONICS CO., LTD., Suwon-si (KR)

(21) Appl. No.: 13/967,733

(22) Filed: Aug. 15, 2013

(30) Foreign Application Priority Data
Dec. 21, 2012 (KR) 10-2012-0150314

(51) Int. Cl. H01L 33/00

(52) U.S. Cl. CPC H01L 33/002
USPC 257/94; 438/47

(57) ABSTRACT

A method of manufacturing a semiconductor light emitting device, includes: forming a plurality of concave portions on a substrate; injecting silica particles into the plurality of concave portions; and forming a semiconductor layer on the substrate, the semiconductor layer including voids formed in portions of the semiconductor layer, the portions being located above the plurality of concave portions.

### CROSS-REFERENCE TO RELATED APPLICATIONS

This application claims priority of Korean Patent Application No. 10-2012-0150314 filed on Dec. 21, 2012, in the Korean Intellectual Property Office, the disclosure of which is incorporated herein by reference.

### TECHNICAL FIELD

Apparatuses and methods consistent with exemplary embodiments relate to a semiconductor light emitting device and a method of manufacturing the same.

### BACKGROUND

A semiconductor light emitting device is able to emit light of various colors due to electron-hole recombination occurring at p-n junctions between p-type and n-type semiconductors when current is applied thereto. Such a semiconductor light emitting device is advantageous over a filament-based light emitting device in that it has a relatively long lifespan, relatively low power consumption, superior initial-operating characteristics, high vibration resistance, and the like. These factors have continually boosted demand for semiconductor light emitting devices.

Notably of late, a great deal of attention has been drawn to group III nitride semiconductors that can emit light in a blue/short wavelength region. Since group III nitrides such as GaN, AN, and the like have high thermal stability and a direct transition energy band structure, they are extensively used in photoelectric devices emitting light in blue and ultraviolet wavelength regions. Particularly, blue and green light emitting devices using GaN are widely used in various technical fields such as flat panel display devices, traffic lights, indoor lighting devices, high density light sources, high resolution output systems, optical communications systems, and the like.

Group III nitride semiconductor layers may be grown on a heterogeneous substrate having a hexagonal crystal structure such as a sapphire substrate, a silicon carbide (SiC) substrate, a silicon (Si) substrate, or the like, by metal organic vapor phase epitaxy (MOVPE), molecular beam epitaxy (MBE) or the like. However, in the case in which the group III nitride semiconductor layer is grown on the heterogeneous substrate, warpage may occur due to a difference in thermal expansion coefficients between the semiconductor layer and the substrate. Accordingly, when an active layer is grown on the semiconductor layer formed on the warped substrate, non-uniformity in temperature distribution may occur, resulting in an increase in wavelength distribution of light. In addition, cracks or warpage may be generated within the semiconductor layer due to differences in lattice constants and thermal expansion coefficients between the semiconductor layer and the substrate, resulting in dislocation. The cracks, warpage and dislocation within the semiconductor layer degrade the characteristics of a light emitting device.

In order to alleviate stress caused by the differences in lattice constants and thermal expansion coefficients between the semiconductor layer and the substrate, a buffer layer has been used. However, despite the use of the buffer layer, the differences in lattice constants and thermal expansion coefficients may still cause cracks within the semiconductor layer or damage to the substrate.

### SUMMARY

One or more exemplary embodiments provide a semiconductor light emitting device and a method of manufacturing the same capable of preventing warpage that may be generated due to a difference in thermal expansion coefficients between a semiconductor layer and a heterogeneous substrate when the semiconductor layer is grown on the heterogeneous substrate formed of a different material from that of the semiconductor layer.

One or more exemplary embodiments also provide a method of growing a semiconductor layer with reduced crystalline defects by preventing the occurrence of cracks within the semiconductor layer.

One or more exemplary embodiments also provide a semiconductor light emitting device that is less affected by a lattice constant and a thermal expansion coefficient of a substrate and a method of manufacturing the same.

According to an aspect of an exemplary embodiment, there is provided a method of manufacturing a semiconductor light emitting device, the method including: forming a plurality of concave portions in a surface of a substrate; injecting silica particles into the plurality of concave portions; and forming a semiconductor layer on the surface of the substrate having the plurality of concave portions, the semiconductor layer including a surface having a plurality of voids formed at locations facing the plurality of concave patterns.

The plurality of concave portions may be formed by etching the substrate.

The substrate may be formed of at least one selected from the group consisting of Si, Al₂O₃, SiC, MgAl₂O₄, MgO, LiAlO₂ and LiGaO₂.

The semiconductor layer may be formed by a lateral growth method.

A light emitting structure may be formed on the semiconductor layer.

According to another aspect of an exemplary embodiment, there is provided a semiconductor light emitting device including: a substrate including a surface having a plurality of concave portions which silica particles are disposed; a semiconductor layer disposed on the substrate and including a surface having a plurality of voids provided at locations facing the plurality of concave portions; a light emitting structure disposed on the semiconductor layer and including a first conductivity type semiconductor layer, an active layer and a second conductivity type semiconductor layer; and first and second electrodes connected to the first and second conductivity type semiconductor layers, respectively.

The substrate may be formed of at least one selected from the group consisting of Si, Al₂O₃, SiC, MgAl₂O₄, MgO, LiAlO₂ and LiGaO₂.

Each of the plurality of concave portions may have a depth of 5 nm to 5 μm.

The plurality of concave portions may have an interval of 1 nm to 10 μm therebetween.

The plurality of concave patterns may form a pattern having a quadrangular shape.

The quadrangular shape may have a side length of 5 nm to 5 μm.

The plurality of concave portions may form a pattern having a circular shape.

The circular shape may have a diameter of 5 nm to 5 μm.

The silica particles may be spherical-shaped silica balls.

The silica balls may have a diameter of 5 nm to 5 μm.

### BRIEF DESCRIPTION OF THE DRAWINGS

The above and other aspects will be more clearly understood from the following detailed description of exemplary embodiments taken in conjunction with the accompanying drawings, in which:

FIGS. 1 through 7 are views illustrating a method of manufacturing a semiconductor light emitting device according to an exemplary embodiment;

FIGS. 8 and 9 are graphs representing tables 1 and 2;

FIG. 10 is a cross-sectional view illustrating a semiconductor light emitting device including a substrate and semiconductor layers formed thereon according to an exemplary embodiment;

FIGS. 11 and 12 illustrate examples of applying a semiconductor light emitting device according to an exemplary embodiment to packages;

FIGS. 13 and 14 illustrate examples of applying a semiconductor light emitting device according to an exemplary embodiment to backlight units;

FIG. 15 illustrates an example of applying a semiconductor light emitting device according to an exemplary embodiment to a lighting device; and

FIG. 16 illustrates an example of applying a semiconductor light emitting device according to an exemplary embodiment to a headlamp.

### DETAILED DESCRIPTION OF EXEMPLARY EMBODIMENTS

Exemplary embodiments of the inventive concept will now be described in detail with reference to the accompanying drawings.

The inventive concept may, however, be exemplified in many different forms and should not be construed as being limited to the specific exemplary embodiments set forth herein. Rather, these exemplary embodiments are provided so that this disclosure will be thorough and complete, and will fully convey the scope of the inventive concept to those skilled in the art.

In the drawings, the shapes and dimensions of elements may be exaggerated for clarity, and the same reference numerals will be used throughout to designate the same or like elements.

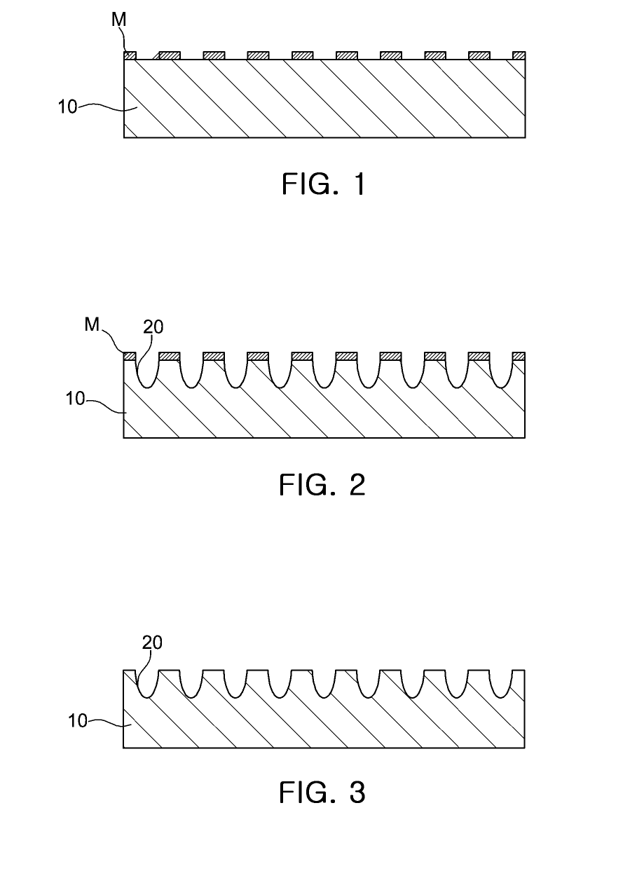

FIGS. 1 through 7 are views illustrating a method of manufacturing a semiconductor light emitting device according to an exemplary embodiment.

As shown in FIG. 1, a mask M having patterns at regular intervals is disposed on a substrate 10 on which a semiconductor light emitting device is to be formed.

The substrate 10 may be provided for semiconductor growth. The substrate 10 may be made of a semiconductor material having insulating and conducting properties such as sapphire, SiC, MgAl₂O₄, MgO, LiAlO₂, LiGaO₂, GaN or the like. A sapphire substrate widely used as a semiconductor growth substrate is formed of a crystal having Hexa-Rhombo R3c symmetry, and has a lattice constant of 13.001 Å in a C-axis and a lattice constant of 4.758 Å in an A-axis. Orientation planes of the sapphire substrate include a C (0001) plane, an A (1120) plane, an R (1102) plane, and the like. In particular, the C plane is mainly used as a substrate for nitride growth as it facilitates the growth of a nitride film and is stable at high temperatures. A silicon (Si) substrate may also be appropriate to be used as the substrate 10. The use of a silicon substrate, which should have a large diameter and be relatively low in price, may facilitate mass-production. In the case in which a silicon substrate is used, a nucleation layer made of AlₓGa₁₋ₓN may be formed on the substrate 10 and a nitride semiconductor having a desired structure may be grown thereon.

However, such a sapphire or silicon (Si) substrate and a semiconductor layer grown thereon, for example, a nitride semiconductor layer, may have relatively large differences in terms of lattice constants and thermal expansion coefficients. In order to obtain a high quality semiconductor layer, a buffer structure capable of alleviating such differences may be used.

Next, as shown in FIG. 2, the substrate 10 is subjected to an etching process using the mask M. Accordingly, a portion of the substrate 10 on which the mask M is not formed is etched such that one or more concave portions 20 are formed in a top surface of substrate 10. The etching of the substrate 10 may be performed with wet etching or dry etching. The concave portions 20 may be grooves or depressions in the top surface of the substrate 10 and may be arranged to form a pattern or have a regular shape.

Then, as shown in FIG. 3, the mask M is removed from the substrate 10.

When viewed from a top surface of the substrate 10, a pattern or shape formed by the one or more concave portions 20 may be circular, quadrangular, stripes or the like. Here, the quadrangular shape includes a trapezoidal shape, a rectangular shape and a square shape. Here, a depth of the concave portions 20 may be 5 nm to 5 μm or an interval between the concave portions 20 may be 1 nm to 10 μm.

For example, in the case in which the shape of the concave portion 20 is circular, a diameter thereof may be 5 nm to 5 μm, and in the case in which the cross-section of the concave portion 20 is quadrangular, a length of sides thereof may be 5 nm to 5 μm.

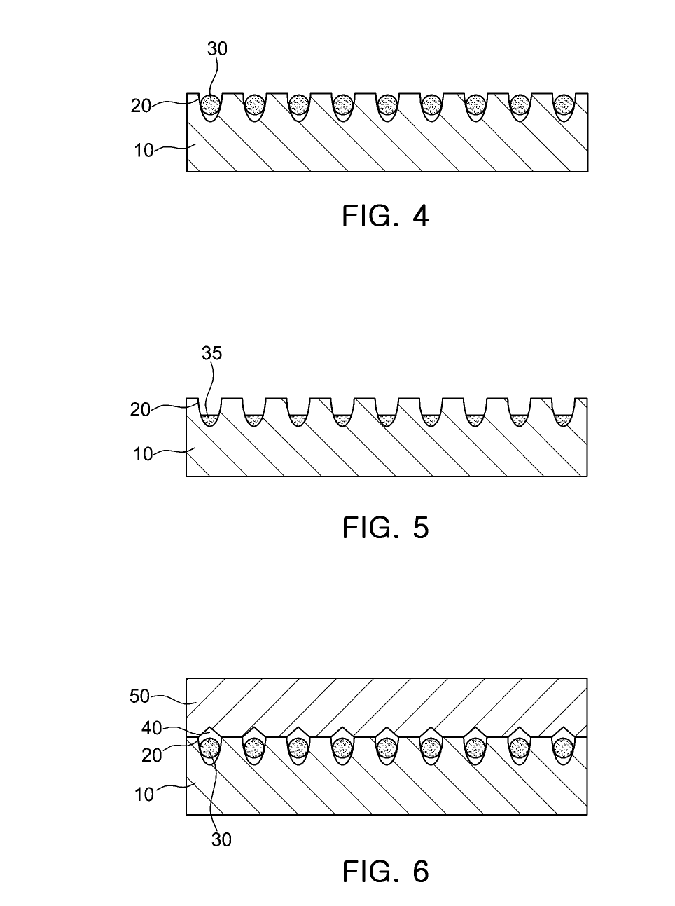

Thereafter, as shown in FIG. 4, at least one silica particle 30 may be provided in each concave portion 20. The silica particle 30 may be made of SiO₂ and may be variously shaped. In addition, the silica particle 30 may have a size sufficient to be injected into the concave portion 20. However, a portion of the silica particle 30 may be protruded from an upper surface of the concave portion 20. For example, in the case in which the silica particle 30 is a spherical shaped silica ball, a diameter thereof may be 5 nm to 5 μm.

In FIG. 4, a single silica particle 30 is injected into each concave portion 20. However, the inventive concept is not limited thereto. A plurality of silica particles 30 may be injected into each concave portion 20 according to the size of the silica particles 30.

Alternatively, as shown in FIG. 5, a thin film 35 made of SiO₂ may be formed in the concave portions 20, instead of injecting the silica particle 30 into the concave portions 20.

Then, as shown in FIG. 6, a lower semiconductor layer 50 may be grown on the substrate 10.

When the lower semiconductor layer 50 is laterally grown on the substrate 10 under favorable conditions for lateral growth using metal organic chemical vapor deposition (MOCVD), epitaxial growth, or the like, the growth of the lower semiconductor layer 50 may be initiated on a portion of the substrate 10 in which the concave portion 20 is not formed, while the lower semiconductor layer 50 may not be grown on a portion thereof in which the concave portion 20 is formed. In particular, the growth of the lower semiconductor layer 50 over the concave portion 20 may be disturbed due to the silica particle 30 injected into the concave portion 20. Therefore, the lower semiconductor layer 50 may include a plurality of voids 40 formed above the concave portions 20. The voids 40 may reduce a contact area between the substrate 10 and the lower semiconductor layer 50 formed on the substrate 10, thereby alleviating stress caused by the differences in lattice constants and thermal expansion coefficients between the substrate and the lower semiconductor layer 50.

Here, the lower semiconductor layer 50 may be an undoped semiconductor layer and serve as an additional buffer, but is not limited thereto. The lower semiconductor layer 50 may form a portion of a light emitting structure.

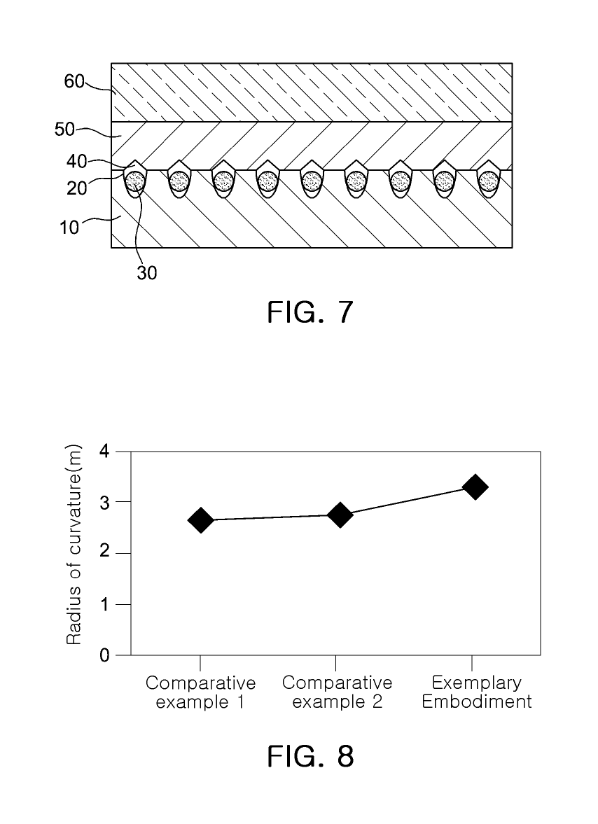

Then, as shown in FIG. 7, a light emitting structure 60 may be formed on the lower semiconductor layer 50.

The light emitting structure 60 may include a first conductivity type semiconductor layer, an active layer and a second conductivity type semiconductor layer sequentially stacked, and a first electrode formed on a portion of the first conductivity type semiconductor layer exposed by etching portions of the active layer and the second conductivity type semiconductor layer, and a second electrode formed on the second conductivity type semiconductor layer.

Alternatively, the light emitting structure 60 may include a first conductivity type semiconductor layer, an active layer and a second conductivity type semiconductor layer sequentially stacked, and a first electrode formed on the first conductivity type semiconductor layer, and a second electrode formed on the second conductivity type semiconductor layer.

Here, the first conductivity type semiconductor layer of the light emitting structure 60 may be formed by doping the lower semiconductor layer 50 with impurities.

As discussed above, the contact area between the substrate 10 and the semiconductor layer 50 formed on the substrate 10 may be reduced to thereby alleviate warpage caused by the differences in thermal expansion coefficients between the substrate 10 and the semiconductor layer 50. In addition, the silica particles 30 injected into the concave portions 20 may serve to withstand stress in a direction in which the substrate 10 is warped, thereby effectively preventing the warpage of the substrate 10.

Accordingly, the semiconductor layer 50 may not be affected by the lattice constant and the thermal expansion coefficient of the substrate 10. When the semiconductor layer 50 is obtained in this manner, crystalline quality may be improved. Therefore, an additional process for preventing damage to the semiconductor layer 50 may be omitted.

In addition, the voids 40 formed in the surface of the semiconductor layer 50 that faces and contacts the substrate 10 may serve as a stress buffer, such that cracks occurring due to the difference in thermal expansion coefficients between the substrate 10 and the semiconductor layer 50 may be significantly reduced.

Furthermore, the concave portions 20 formed on the substrate 10 may have an effect on improvement of light extraction efficiency, and light extraction efficiency may be improved according to a difference in refractive index between the substrate 10 and the inside of the voids 40.

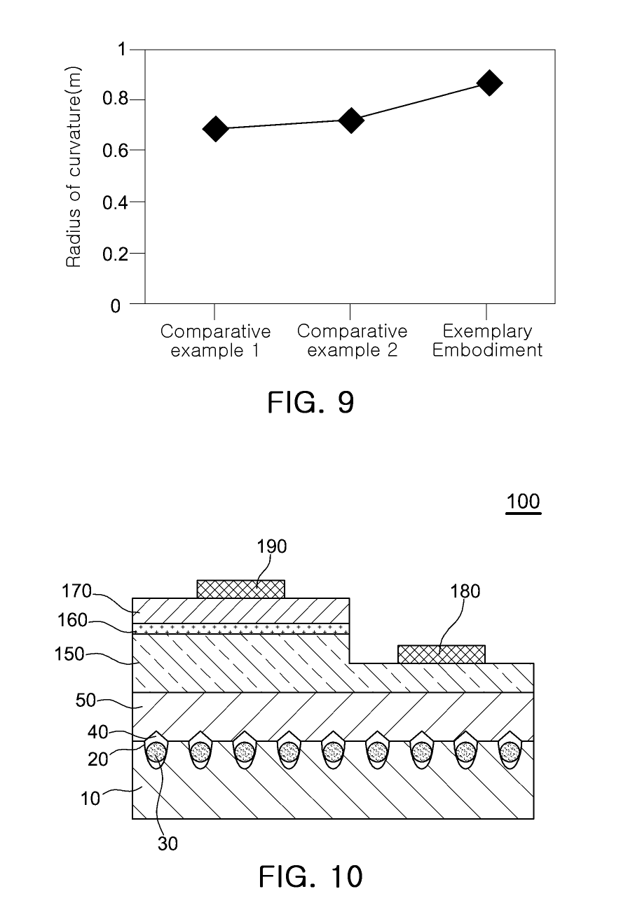

Tables 1 and 2 illustrate the radii of curvature of substrates according to exemplary embodiments and comparative examples by comparing a case in which a semiconductor layer is grown on a substrate having concave portions according to an exemplary embodiment with cases in which a semiconductor layer is grown on a substrate having a flat top surface without concave portions (comparative example 1) and on a patterned sapphire substrate (PSS) (comparative example 2). Here, Table 1 indicates the radii of curvature measured at 1000° C. while a GaN semiconductor layer is formed on a sapphire substrate, and Table 2 indicates the radii of curvature measured after the GaN semiconductor layer formed on the sapphire substrate is cooled. Also, FIGS. 8 and 9 are graphs representing Tables 1 and 2.

TABLE 1

| Comparative | | |
|---|---|---|
| Example 1 | Comparative Example 2 | Exemplary Embodiment |
| 2.64 m | 2.78 m | 3.3 m |

TABLE 2

| Comparative | | |
|---|---|---|
| Example 1 | Comparative Example 2 | Exemplary Embodiment |
| 0.68 m | 0.714 m | 0.848 m |

As shown in Table 1 and FIG. 8, when the radius of curvature is measured while the GaN semiconductor layer is formed on the sapphire substrate, the radius of curvature of the substrate (exemplary embodiment) having the concave portions is much greater than that of the substrate (comparative example 1) having the flat top surface and that of the patterned sapphire substrate (comparative example 2). In addition, as shown in Table 2 and FIG. 9, when the radius of curvature is measured after the GaN semiconductor layer is formed on the sapphire substrate, the radius of curvature of the substrate (exemplary embodiment) having the concave portions is much greater than that of the substrate (comparative example 1) having the flat top surface and that of the patterned sapphire substrate (comparative example 2). That is, it can be seen that the substrate according to the exemplary embodiment has less warpage than the substrate having the flat top surface (comparative example 1) and the patterned sapphire substrate (comparative example 2).

FIG. 10 is a cross-sectional view illustrating a semiconductor light emitting device including a substrate and semiconductor layers formed thereon, according to an exemplary embodiment.

With reference to FIG. 10, a semiconductor light emitting device 100 according to an exemplary embodiment may include a lower semiconductor layer 50 formed on a substrate 10, and a light emitting structure formed on the lower semiconductor layer 50, the light emitting structure including a first conductivity type semiconductor layer 150, an active layer 160, and a second conductivity type semiconductor layer 170 sequentially stacked and first and second electrodes 180 and 190.

The substrate 10 is a wafer for manufacturing a semiconductor light emitting device. The substrate 10 may be formed of at least one selected from the group consisting of Si, Al₂O₃, SiC, MgAl₂O₄, MgO, LiAlO₂ and LiGaO₂.

A plurality of concave portions 20 may be formed in a top surface of the substrate 10, the concave portions 20 each having at least one silica particle 30 disposed therein.

The lower semiconductor layer 50 may be formed on the substrate 10. The lower semiconductor layer 50 may be formed of a semiconductor material expressed by AlₓIn_{y}Ga_{1-x-y}N (0≦x≦1, 0≦y≦1, 0≦x+y≦1). The lower semiconductor layer 50 may include a void formed in a position corresponding to the concave portion 20 formed in the substrate 10.

The light emitting structure including the first conductivity type semiconductor layer 150, the active layer 160, and the second conductivity type semiconductor layer 170 may be formed on the lower semiconductor layer 50.

The first electrode 180 may be formed on a portion of the first conductivity type semiconductor layer 150 exposed by dry-etching portions of the active layer 160 and the second conductivity type semiconductor layer 170, and the second electrode 190 may be formed on the second conductivity type semiconductor layer 170.

In addition, a transparent electrode may be further formed between the second conductivity type semiconductor layer 170 and the second electrode 190 for current spreading.

The semiconductor light emitting device according to this exemplary embodiment may be less affected by a difference in thermal expansion coefficients between the substrate and the semiconductor layers, thereby preventing warpage, and thus, it may have uniform light characteristics.

In addition, the semiconductor light emitting device may be formed of semiconductor layers having less crystalline defects by being less affected by the lattice constant and thermal expansion coefficient of the substrate. FIG. 10 shows a horizontal-type semiconductor light emitting device; however, the inventive concept is not limited thereto, and may be applied to various types of semiconductor light emitting devices.

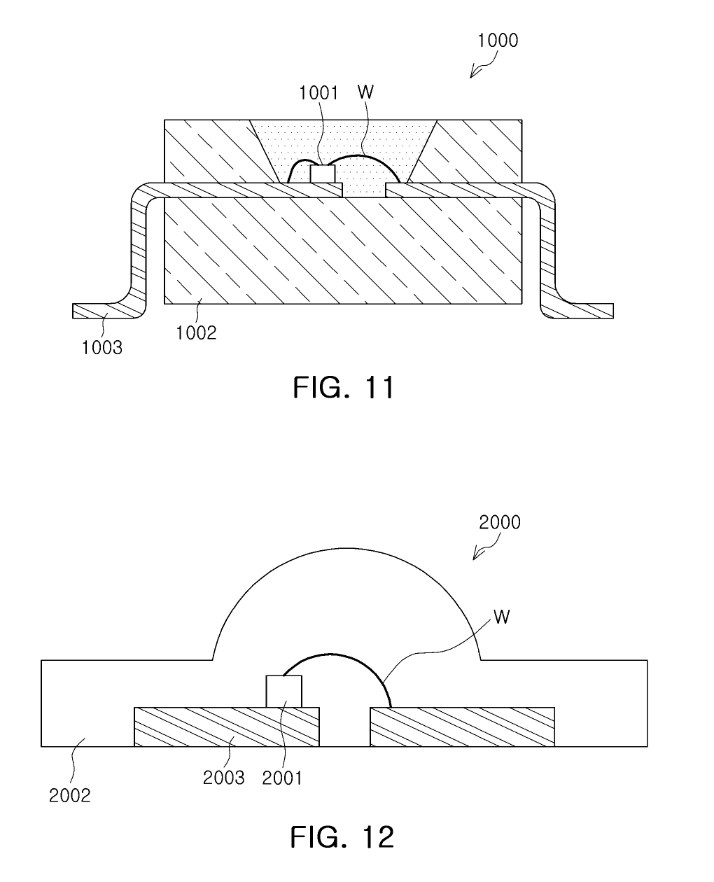

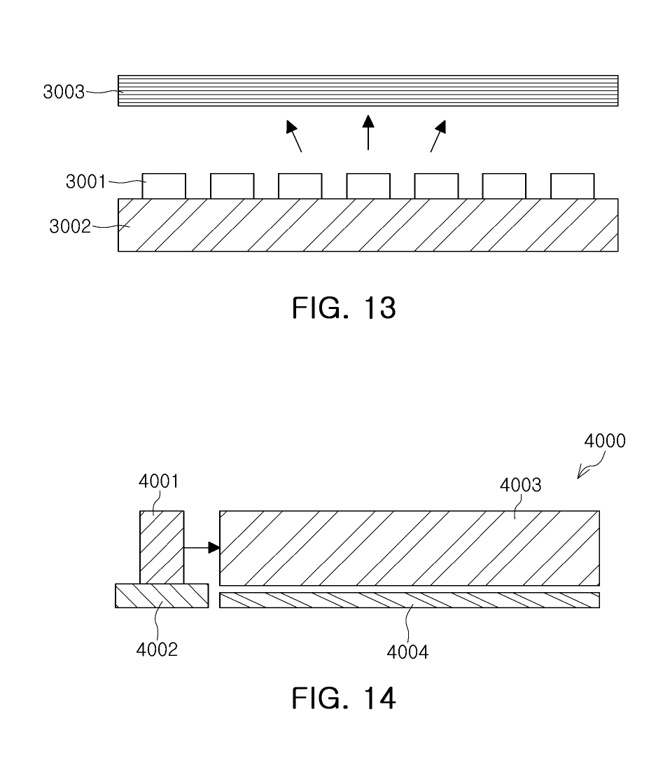

FIGS. 11 and 12 illustrate examples of applying a semiconductor light emitting device according to an exemplary embodiment to packages.

A package 1000 of FIG. 11 includes a semiconductor light emitting device 1001, a package main body 1002 and a pair of lead frames 1003. The semiconductor light emitting device 1001 may be mounted on the lead frame 1003 to be electrically connected thereto through a wire W. The semiconductor light emitting device 1001 may be mounted on another portion of the package 1000 rather than the lead frame 1003, for example, on the package main body 1002. The package main body 1002 may have a cup shape (i.e., a central hollow having sloped sides) as shown in FIG. 11 in order to improve light reflection efficiency, and such a reflective cup may be filled with a light transmissive material encapsulating the semiconductor light emitting device 1001 and the wire W. The semiconductor light emitting device 1001 may have the structure of FIG. 10, or the semiconductor light emitting device 1001 may have different structures. A single wire W may be used or no wire may be used, according to the electrode structure of the semiconductor light emitting device 1001 and the method of mounting the semiconductor light emitting device 1001.

A package 2000 of FIG. 12 is similar to the above-mentioned package 1000, in that a semiconductor light emitting device 2001 is mounted on a pair of lead frames 2003 while making electrical connection therebetween using a wire W. On the other hand, the package 2000 is different from the package 1000, in that a bottom surface of the lead frame 2003 is exposed outwardly to improve the dissipation of heat and the shape of the package 2000 is maintained by a light transmissive main body 2002 encapsulating the semiconductor light emitting device 2001, the wire W and the lead frame 2003. The semiconductor light emitting device 2001 may have the above-described structure and utilize a single wire W as shown in FIG. 12. However, the number of wires may be changed according to the electrode structure of the semiconductor light emitting device 2001 and the method of mounting the semiconductor light emitting device 2001.

FIGS. 13 and 14 illustrate examples of applying a semiconductor light emitting device according to an exemplary embodiment to backlight units. With reference to FIG. 13, a backlight unit 3000 includes a light source 3001 mounted on a substrate 3002 and at least one optical sheet 3003 disposed above the light source 3001 and the substrate 3002. The light source 3001 may be a light emitting device package having the above-described structure or a structure similar thereto. Alternatively, a semiconductor light emitting device may be directly mounted on the substrate 3002 in a chip-on-board (COB) scheme. The light source 3001 in the backlight unit 3000 of FIG. 13 emits light toward a liquid crystal display (LCD) device disposed above the light source 3001, whereas a light source 4001 mounted on a substrate 4002 in a backlight unit 4000 of FIG. 14 emits light laterally and the light is incident to a light guide plate 4003 such that the backlight unit 4000 may serve as a surface light source. The light travelling to the light guide plate 4003 may be emitted upwardly and a reflective layer 4004 may be formed under a bottom surface of the light guide plate 4003 in order to improve light extraction efficiency.

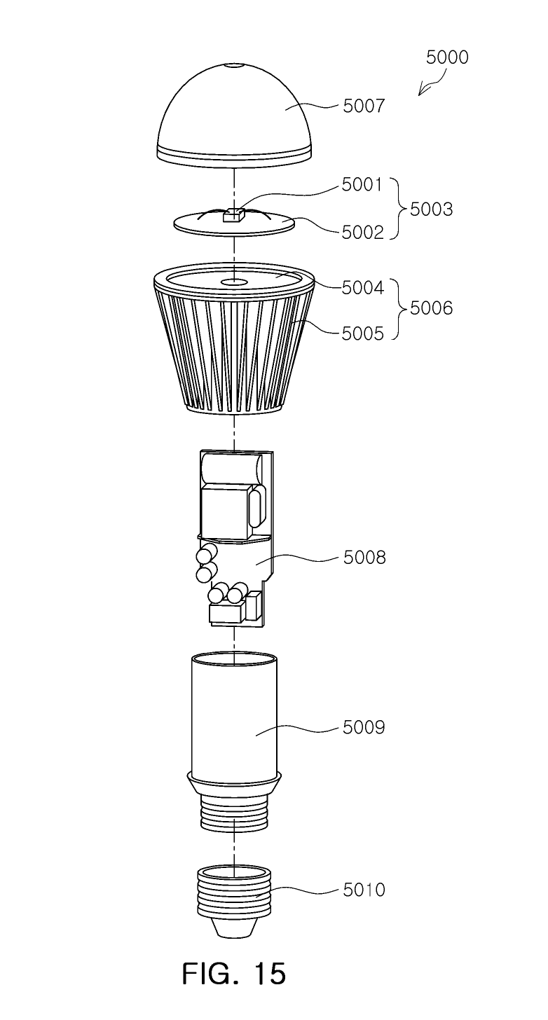

FIG. 15 illustrates an example of applying a semiconductor light emitting device according to an exemplary embodiment to a lighting device. With reference to an exploded perspective view of FIG. 15, a lighting device 5000 is exemplified as a bulb-type lamp, and includes a light emitting module 5003, a driving unit 5008 and an external connector unit 5010. In addition, exterior structures such as an external housing 5006, an internal housing 5009, a cover unit 5007 and the like may be additionally included. The light emitting module 5003 may include a semiconductor light emitting device 5001 and a circuit board 5002 having the semiconductor light emitting device 5001 mounted thereon. In the present exemplary embodiment, a single semiconductor light emitting device 5001 is mounted on the circuit board 5002. However, if necessary, a plurality of semiconductor light emitting devices may be mounted thereon. In addition, the semiconductor light emitting device 5001 may be formed as a package and then mounted on the circuit board 5002, rather than being directly mounted thereon.

In the lighting device 5000, the light emitting module 5003 may include the external housing 5006 serving as a heat radiating part, and the external housing 5006 may include a heat sink plate 5004 in direct contact with the light emitting module 5003 and a plurality of heat radiating fins 5005 exposed outwardly to thereby improve the dissipation of heat. In addition, the lighting device 5000 may include the cover unit 5007 disposed above the light emitting module 5003 and having a convex lens shape. The driving unit 5008 may be disposed inside the internal housing 5009 and connected to the external connector unit 5010 such as a socket structure to receive power from an external power source. In addition, the driving unit 5008 may convert the received power into power appropriate for driving the semiconductor light emitting device 5001 of the light emitting module 5003 and supply the converted power thereto. For example, the driving unit 5008 may be provided as an AC-DC converter, a rectifying circuit part, or the like.

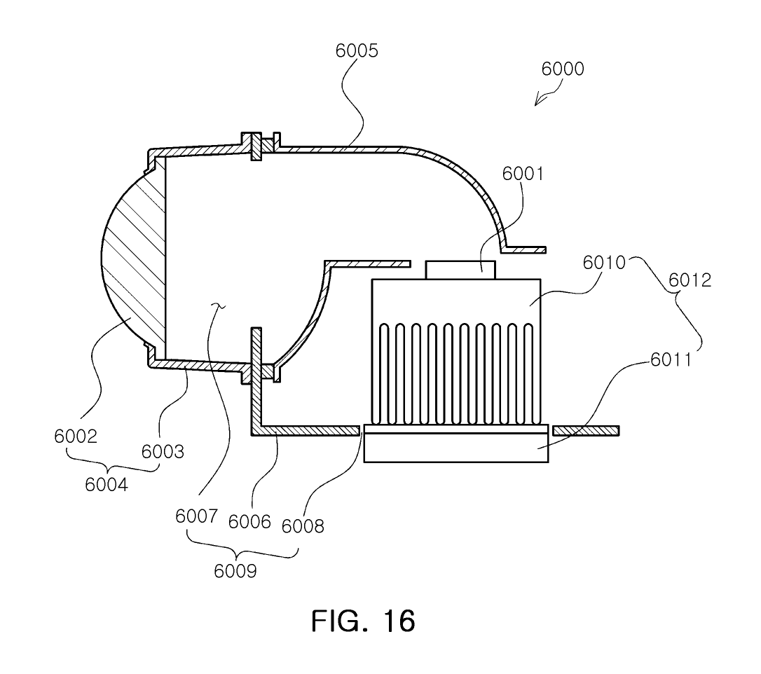

FIG. 16 illustrates an example of applying a semiconductor light emitting device according to an exemplary embodiment to a headlamp. With reference to FIG. 16, a headlamp 6000 used in a vehicle or the like may include a light source 6001, a reflective unit 6005 and a lens cover unit 6004, the lens cover unit 6004 including a hollow guide part 6003 and a lens 6002. In addition, the head lamp 6000 may further include a heat radiating unit 6012 dissipating heat generated by the light source 6001 outwardly. The heat radiating unit 6012 may include a heat sink 6010 and a cooling fan 6011 in order to effectively dissipate heat. In addition, the headlamp 6000 may further include a housing 6009 allowing the heat radiating unit 6012 and the reflective unit 6005 to be fixed thereto and supporting them. One surface of the housing 6009 may be provided with a central hole 6008 into which the heat radiating unit 6012 is inserted to be coupled thereto. In addition, the other surface of the housing 6009 bent in a direction perpendicular to one surface of the housing 6009 may be provided with a forwardly open hole 6007 such that light generated by the light source 6001 may be reflected by the reflective unit 6005 disposed above the light source 6001, pass through the forwardly open hole 6007, and be emitted outwardly.

As set forth above, according to exemplary embodiments, warpage caused by a difference in thermal expansion coefficients between a substrate and a semiconductor layer may be prevented.

In addition, the occurrence of cracks in the semiconductor layer may be prevented, whereby the semiconductor layer, when grown, may have reduced crystalline defects.

Furthermore, a semiconductor light emitting device may be less affected by a lattice constant and a thermal expansion coefficient of the substrate.

While the present inventive concept has been shown and described in connection with the exemplary embodiments, it will be apparent to those skilled in the art that modifications and variations can be made without departing from the spirit and scope of the inventive concept as defined by the appended claims.

What is claimed is:

1. A method of manufacturing a semiconductor light emitting device, the method comprising:
forming a plurality of concave portions in a surface of a substrate;
injecting silica particles into the plurality of concave portions; and
forming a semiconductor layer on the surface of the substrate having the plurality of concave portions, the semiconductor layer comprising a surface having a plurality of voids formed at locations facing the plurality of concave portions.

2. The method of claim 1, wherein the forming the plurality of concave portions comprises forming the plurality of concave portions by etching the substrate.

3. The method of claim 1, wherein the substrate is formed of at least one selected from the group consisting of Si, Al₂O₃, SiC, MgAl₂O₄, MgO, LiAlO₂ and LiGaO₂.

4. The method of claim 1, wherein the forming the semiconductor layer comprises forming the semiconductor layer on the surface of the substrate by a lateral growth method.

5. The method of claim 1, further comprising forming a light emitting structure on the semiconductor layer.

6. A semiconductor light emitting device comprising:
a substrate comprising a surface having a plurality of concave portions in which silica particles are disposed;
a semiconductor layer disposed on the substrate and comprising a surface having a plurality of voids provided at locations facing the plurality of concave portions;
a light emitting structure disposed on the semiconductor layer, the light emitting structure comprising a first conductivity type semiconductor layer, an active layer and a second conductivity type semiconductor layer; and
first and second electrodes connected to the first and second conductivity type semiconductor layers, respectively.

7. The semiconductor light emitting device of claim 6, wherein the substrate is formed of at least one selected from the group consisting of Si, Al₂O₃, SiC, MgAl₂O₄, MgO, LiAlO₂ and LiGaO₂.

8. The semiconductor light emitting device of claim 6, wherein each of the plurality of concave portions has a depth of 5 nm to 5 μm.

9. The semiconductor light emitting device of claim 6, wherein the plurality of concave portions are space apart by an interval of 1 nm to 10 μm.

10. The semiconductor light emitting device of claim 6, wherein the plurality of concave portions form a pattern having a quadrangular shape.

11. The semiconductor light emitting device of claim 10, wherein the quadrangular shape has a side length of 5 nm to 5 μm.

12. The semiconductor light emitting device of claim 6, wherein the plurality of concave portions form a pattern having a circular shape.

13. The semiconductor light emitting device of claim 12, wherein the circular shape has a diameter of 5 nm to 5 μm.

14. The semiconductor light emitting device of claim 6, wherein the silica particles comprise spherical-shaped silica balls.

15. The semiconductor light emitting device of claim 14, wherein each of the silica balls has a diameter of 5 nm to 5 μm.

16. A semiconductor device comprising:
a substrate formed of a first material, the substrate comprising a surface having a plurality of grooves formed therein;
a second material disposed inside the grooves, the second material being different from the first material; and
a semiconductor layer comprising a surface contacting the surface of the substrate at areas between the grooves and being spaced apart from the second material disposed inside the openings.

17. The semiconductor device of claim 16, wherein the first material comprises one of Si, Al₂O₃, SiC, MgAl₂O₄, MgO, LiAlO₂ and LiGaO₂, and the second material comprises silica.

18. The semiconductor device of claim 17, wherein the silica is formed as spherically shaped silica balls.

19. The semiconductor device of claim 16, wherein the grooves have a concave cross section.

20. The semiconductor device of claim 16, wherein the grooves are spaced apart from each other at equal length intervals.
